(19) United States
(12) Patent Application Publication
(10) Pub. No.: US 2025/0300003 A1
(43) Pub. Date: Sep. 25, 2025

(54) FRAME UNIT FORMING METHOD, FRAME UNIT FORMING APPARATUS, AND METHOD OF FORMING DEVICE CHIPS

(71) Applicant: DISCO CORPORATION, Tokyo (JP)

(72) Inventor: Masaru NAKAMURA, Tokyo (JP)

(21) Appl. No.: 19/066,492

(22) Filed: Feb. 28, 2025

(30) Foreign Application Priority Data
Mar. 22, 2024 (JP) 2024-046233

(51) Int. Cl. H01L 21/687; H01L 21/677; H01L 21/683

(52) U.S. Cl. CPC H01L 21/68785; H01L 21/6779; H01L 21/6836; H01L 21/68771

(57) ABSTRACT

A frame unit forming method includes disposing a wafer on an opening portion of an annular frame, forming a frame unit by disposing a thermocompression bonding sheet on the wafer and an outer periphery of the annular frame and integrating the wafer with the annular frame by the thermocompression bonding sheet, and, activating, before forming the frame unit, a surface of the thermocompression bonding sheet on a side which is to be disposed on the wafer and the annular frame, by applying plasma processing or corona treatment to the surface of the thermocompression bonding sheet.

### BACKGROUND OF THE INVENTION

### Field of the Invention

The present invention relates to a frame unit forming method and a frame unit forming apparatus.

### Description of the Related Art

A wafer which has a face side on which a plurality of devices exemplified by integrated circuits (ICs) and large scale integration (LSI) circuits are formed by being divided by a plurality of projected dicing lines is diced into individual device chips by a cutting apparatus that has a cutting blade in a rotatable manner, and the device chips obtained by dicing are used for electronic appliances including mobile phones and personal computers.

Before being loaded into the cutting apparatus, the wafer is positioned at an opening portion of an annular frame for housing the wafer, and a dicing tape is affixed to a reverse side of the wafer, so that a frame unit is formed.

The wafer integrated with the annular frame in the frame unit is diced into individual device chips by the cutting apparatus, and is thereafter conveyed to a pickup step in a state in which the form of the wafer is maintained. Subsequently, individual device chips are picked up from the dicing tape and then bonded to a wiring substrate etc. (see, for example, Japanese Patent No. 3076179).

### SUMMARY OF THE INVENTION

Yet, the dicing tape configured by a glue layer being laid on an upper surface of a vinyl chloride sheet poses such a problem that, when the wafer is cut by a cutting blade, glue scatters together with cutting water and sticks to the surface of the device to lower the quality of device chips.

Moreover, forming a dicing groove or an initiating point for dicing by application of a laser beam to each of the projected dicing lines of the wafer also poses the problem of glue of the dicing tape sticking to the devices to cause lowered quality of device chips and eventually become the source of contamination in the pickup step.

It is accordingly an object of the present invention to provide a method and an apparatus for forming a frame unit that does not lower the quality of device chips when a wafer is diced, and a method for forming device chips that does not lower the quality of the device chips when a wafer is diced.

In accordance with an aspect of the present invention, there is provided a frame unit forming method of forming a frame unit by integrating a wafer with an annular frame that has, at its center, an opening portion for housing the wafer, the frame unit forming method including disposing the wafer on the opening portion of the annular frame, forming the frame unit by disposing a thermocompression bonding sheet on the wafer and an outer periphery of the annular frame and integrating the wafer with the annular frame by the thermocompression bonding sheet, and activating, before forming the frame unit, a surface of the thermocompression bonding sheet on a side which is to be disposed on the wafer and the annular frame, by applying plasma processing or corona treatment to the surface of the thermocompression bonding sheet.

Preferably, in the activating, plasma processing or corona treatment is applied to a surface of the wafer and a surface of the annular frame on a side which is to be disposed on a thermocompression bonding sheet, to activate the surfaces of the wafer and the annular frame. Preferably, in the activating, atmospheric plasma processing is applied.

In accordance with another aspect of the present invention, there is provided a frame unit forming apparatus for forming a frame unit with use of a thermocompression bonding sheet by housing a wafer in an opening portion of an annular frame that is provided at a center thereof for housing the wafer, the frame unit forming apparatus including a frame housing unit that houses a plurality of the annular frames, a wafer housing unit that houses a plurality of wafers, a frame conveying mechanism that unloads the annular frame from the frame housing unit and places the unloaded annular frame on a frame table, a thermocompression bonding sheet disposing unit that disposes the thermocompression bonding sheet on the annular frame placed on the frame table, a frame sheet conveying mechanism that conveys the annular frame on which the thermocompression bonding sheet is disposed to a frame unit forming table, a wafer unloading mechanism that unloads the wafer from the wafer housing unit and conveys the unloaded wafer to the frame unit forming table, a frame unit forming mechanism that forms the frame unit by integrating the wafer with the annular frame on which the thermocompression bonding sheet is disposed and which has been conveyed to the frame unit forming table, a cassette housing unit that houses the frame unit in a cassette, and an activation unit that applies plasma processing or corona treatment to the thermocompression bonding sheet on a side which is to be disposed on the annular frame by the thermocompression bonding sheet disposing unit.

Preferably, the frame unit forming apparatus further includes a wafer activation unit that applies plasma processing or corona treatment to the wafer that has been conveyed to the frame unit forming table.

In accordance with a further aspect of the present invention, there is provided a method of forming device chips, the method of forming device chips including disposing a wafer on an opening portion of an annular frame, forming a frame unit by disposing a thermocompression bonding sheet on the wafer and an outer periphery of the annular frame and integrating the wafer with the annular frame by the thermocompression bonding sheet, dividing, after the forming the frame unit, the wafer into individual device chips, and activating, before the forming the frame unit, a surface of the thermocompression bonding sheet on a side which is to be disposed on the wafer and the annular frame, by applying plasma processing or corona treatment to the surface of the thermocompression bonding sheet.

According to the present invention, the frame unit is formed with use of a thermocompression bonding sheet including no glue layer, so that the problem of glue scattering together with cutting water and sticking to the face sides of the devices to lower the quality of the device chips when the wafer is cut by the cutting blade is resolved. Moreover, even when a dicing groove or an initiating point for dicing is formed with application of a laser beam to each of the projected dicing lines of the wafer, since the thermocompression bonding sheet includes no glue layer, the problem of glue sticking to the devices to lower the quality of the device chips and to eventually become the source of contamination in the subsequent pickup step is resolved.

Further, according to the present invention, plasma processing or corona treatment is applied to the surface of the thermocompression bonding sheet on the side which is to be disposed on the wafer and the annular frame, to activate the surface of the thermocompression bonding sheet, and hence, the adhesiveness of the thermocompression bonding sheet with respect to the wafer and the annular frame is enhanced. Moreover, no water in which processing swarf generated at the time of dicing by a cutting blade is mixed would enter any portion between the thermocompression bonding sheet and the wafer. Consequently, lowered quality of device chips is prevented.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is an exploded perspective view illustrating a disposing step;

FIG. 1B is a perspective view illustrating a state in which a wafer is disposed on an opening portion of an annular frame;

FIG. 2 is a perspective view illustrating an activation step;

FIG. 3 is a perspective view illustrating a frame unit forming step;

FIG. 4 is a perspective view of a frame unit;

FIG. 5 is a perspective view illustrating a dicing step using a cutting apparatus;

FIG. 6 is a perspective view illustrating the dicing step using a laser processing apparatus;

FIG. 7A is a cross sectional view of the wafer to which ablation processing has been applied;

FIG. 7B is a cross sectional view of the wafer in which modified layers have been formed;

FIG. 8 is a cross sectional view illustrating a pickup step;

FIG. 9 is a perspective view of a frame unit forming apparatus;

FIG. 10 is a perspective view of a frame housing unit and other members illustrated in FIG. 9;

FIG. 11A is a perspective view of a wafer housing unit and other members illustrated in FIG. 9;

FIG. 11B is a perspective view of a hand illustrated in FIG. 11A;

FIG. 12 is a perspective view of a thermocompression bonding sheet disposing unit and an activation unit illustrated in FIG. 9;

FIG. 13 is a side elevational view of the thermocompression bonding sheet disposing unit and the activation unit illustrated in FIG. 9;

FIG. 14 is a side elevational view illustrating a state in which a thermocompression bonding sheet is thermocompression-bonded to one end of the annular frame with a heating roller positioned at a lower side pressing position;

FIG. 15 is a side elevational view illustrating a state in which the heating roller has been moved from the state illustrated in FIG. 14;

FIG. 16 is a side elevational view illustrating a state in which the heating roller has further been moved from the state illustrated in FIG. 15;

FIG. 17 is an exploded perspective view illustrating a frame unit forming mechanism illustrated in FIG. 9;

FIG. 18 is a perspective view illustrating an inverting mechanism of a cassette housing unit illustrated in FIG. 9;

FIG. 19 is a perspective view of a frame unit supporting section and a pushing-in section of the cassette housing unit illustrated in FIG. 9; and

FIG. 20 is a perspective view illustrating a state in which a cassette housing step is performed.

### DETAILED DESCRIPTION OF THE PREFERRED EMBODIMENT

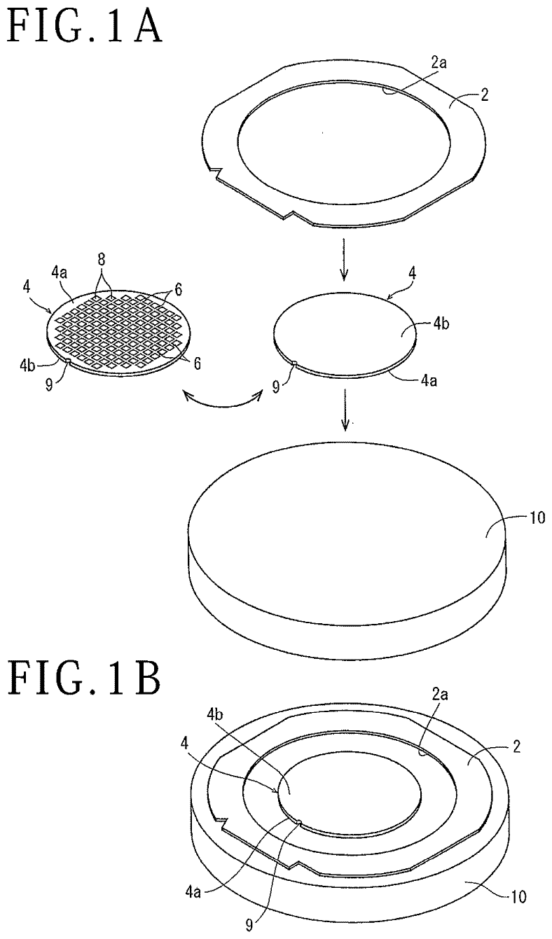

First, a preferred embodiment of a frame unit forming method according to the present invention is explained with reference to FIGS. 1 through 8.

### (Disposing Step)

In the frame unit forming method according to the present embodiment, first, a disposing step of disposing a wafer on an opening portion of an annular frame is carried out.

The annular frame used in the frame unit forming method is, for example, an annular frame 2 illustrated in FIGS. 1A and 1B. At the center of the annular frame 2, a circular opening portion 2a of a size capable of housing a wafer 4 is formed. The wafer 4 can, for example, be formed of an appropriate semiconductor material such as silicon. The wafer 4 has a face side 4a divided into a plurality of rectangular regions by a plurality of projected dicing lines 6 in a grid pattern, and each of the plurality of rectangular regions has a device 8 exemplified by an IC or an LSI circuit formed therein. In a peripheral edge of the wafer 4, a notch 9 for indicating the crystal orientation is formed. In the disposing step, the wafer 4 is disposed on the opening portion 2a of the annular frame 2 with its reverse side 4b oriented upward, and the annular frame 2 and the wafer 4 are placed on an upper surface of a table 10. An electric heater and a temperature sensor (neither of which is illustrated) are incorporated in the table 10, and the temperature of the upper surface of the table 10 may be adjusted by an appropriate control apparatus.

### (Activation Step)

After the disposing step is performed, an activation step of activating a surface of a thermocompression bonding sheet on the side which is to be disposed on the wafer 4 and the annular frame 2, by applying plasma processing or corona treatment to the surface, is carried out.

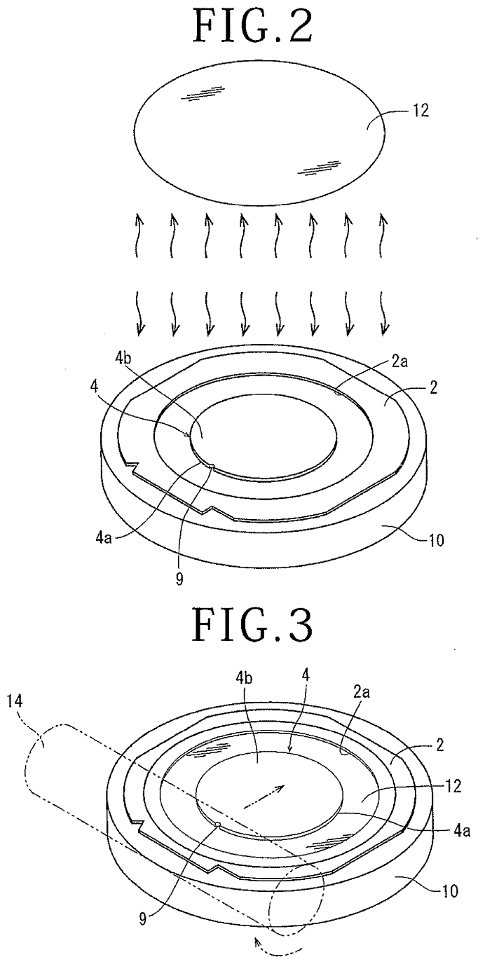

As illustrated in FIG. 2, the thermocompression bonding sheet denoted by 12 that is to be disposed on the wafer 4 and the annular frame 2 is a circular sheet and has a diameter slightly greater than the diameter of the opening portion 2a of the annular frame 2. The thermocompression bonding sheet 12 has no glue layer (adhesive layer) but exhibits adhesion by softening or melting when being heated to a temperature near the melting point. The thermocompression bonding sheet 12 is a thermoplastic synthetic resin sheet and may, for example, be a polyolefin sheet or a polyester sheet. Polyolefin sheets usable as the thermocompression bonding sheet 12 include, for example, polyethylene (PE) sheets, polypropylene (PP) sheets, and polystyrene (PS) sheets. Further, polyester sheets usable as the thermocompression bonding sheet 12 include, for example, polyethylene terephthalate (PET) sheets and polyethylene naphthalate (PEN) sheets.

In the present embodiment, since the thermocompression bonding sheet 12 is disposed on an upper surface (reverse side 4b) of the wafer 4 and an upper surface of the annular frame 2 that are placed on the table 10, in the activation step, plasma processing or corona treatment is applied to a lower surface of the thermocompression bonding sheet 12 illustrated in FIG. 2, to activate the lower surface of the thermocompression bonding sheet 12. This can improve the wettability of the surface of the thermocompression bonding sheet 12 on the side which is to be disposed on the wafer 4 and the annular frame 2. Note that the processing to be performed in the activation step may be atmospheric plasma-processing.

As illustrated in FIG. 2, in the activation step, it is preferable that plasma processing or corona treatment be applied to the surface of the wafer 4 (the reverse side 4b in the present embodiment) and the surface of the annular frame 2 on the side which is to be disposed on the thermocompression bonding sheet 12 and the surfaces of the wafer 4 and the annular frame 2 be activated. This can improve the wettability of the surface of the wafer 4 and the surface of the annular frame 2 on the side which is to be disposed on the thermocompression bonding sheet 12.

In the activation step, before plasma processing or corona treatment is to be applied, organic matter may be destroyed by application of ultraviolet rays to the surface to which plasma processing or corona treatment is to be applied.

### (Frame Unit Forming Step)

After the activation step is performed, a frame unit forming step of forming a frame unit by disposing the thermocompression bonding sheet 12 on the wafer 4 and the outer periphery of the annular frame 2 and integrating the wafer 4 with the annular frame 2 by the thermocompression bonding sheet 12 is carried out.

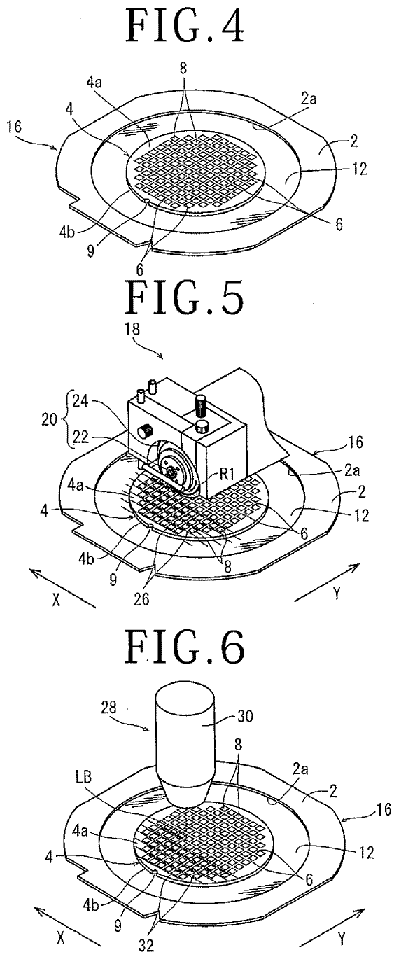

In the frame unit forming step, as illustrated in FIG. 3, after the thermocompression bonding sheet 12 is disposed on the wafer 4 and the outer periphery of the annular frame 2, a heating roller 14 adjusted to a temperature at which the thermocompression bonding sheet 12 exhibits adhesion by softening or melting presses the thermocompression bonding sheet 12 downward while being rolled, to heat and cause the thermocompression bonding sheet 12 to exhibit adhesion. As a result, the softened thermocompression bonding sheet 12 is brought into tight contact with the reverse side 4b of the wafer 4 and the outer periphery of the annular frame 2, and is also thermocompression-bonded to the reverse side 4b of the wafer 4 by the adhesion thereof. Consequently, a frame unit 16 in which the wafer 4 is integrated with the annular frame 2 by the thermocompression bonding sheet 12 can be formed (see FIG. 4).

In the heating roller 14 illustrated in FIG. 3, an electric heater and a temperature sensor (neither of which is illustrated) are incorporated, and the temperature of an outer peripheral surface of the heating roller 14 is adjusted by an appropriate control apparatus. The outer peripheral surface of the heating roller 14 is coated with fluorine resin, and hence, the thermocompression bonding sheet 12 does not stick to the heating roller 14 even when exhibiting adhesion. Note that, in the frame unit forming step, instead of the temperature of the heating roller 14 being adjusted, the temperature of the upper surface of the table 10 may be adjusted to a temperature at which the thermocompression bonding sheet 12 exhibits adhesion by softening or melting.

The heating temperature of the thermocompression bonding sheet 12 in the present step may, for example, be the following temperature.

### <In the Case of Polyolefin Sheets>

Polyethylene sheets: 120° C. to 140° C.
Polypropylene sheets: 160° C. to 180° C.
Polystyrene sheets: 220° C. to 240° C.

### <In the Case of Polyester Sheets>

Polyethylene terephthalate sheets: 250° C. to 270° C.
Polyethylene naphthalate sheets: 160° C. to 180° C.

As described above, according to the present embodiment, plasma processing or corona treatment is applied, in the activation step, to the thermocompression bonding surface of the thermocompression bonding sheet 12, to improve the wettability of the thermocompression bonding surface of the thermocompression bonding sheet 12, and then, the thermocompression bonding sheet 12 is thermocompression-bonded to the wafer 4 and the annular frame 2 in the frame unit forming step. This can enhance the adhesiveness of the thermocompression bonding sheet 12 with respect to the wafer 4 and the annular frame 2. Moreover, in a case where the wettability of a thermocompression bonding surface of the wafer 4 and a thermocompression bonding surface of the annular frame 2 is improved by application of plasma processing or corona treatment to the thermocompression bonding surface of the wafer 4 and the thermocompression bonding surface of the annular frame 2, the adhesiveness of the thermocompression bonding sheet 12 with respect to the wafer 4 and the annular frame 2 can further be enhanced.

### (Dicing Step)

In the present embodiment, after the frame unit forming step is performed, a dicing step (dividing step, device chip forming step) of dicing (dividing) the wafer 4 into individual device chips is carried out.

The dicing step can be performed, for example, with use of a cutting apparatus 18 illustrated in FIG. 5. The cutting apparatus 18 includes a chuck table (not illustrated) for holding under suction the wafer 4 and a cutting unit 20 for cutting the wafer 4 held under suction on the chuck table. The cutting unit 20 includes a spindle 22 configured to be rotatable about a Y-axis direction (a direction indicated by an arrow Y in FIG. 5) as an axis and an annular cutting blade 24 fixed to a distal end of the spindle 22. Note that an X-axis direction indicated by an arrow X in FIG. 5 is a direction perpendicular to the Y-axis direction. An XY plane defined by the X-axis direction and the Y-axis direction is substantially horizontal.

When the dicing step is to be performed with use of the cutting apparatus 18, first, the wafer 4 is held under suction on an upper surface of the chuck table with the face side 4a of the wafer 4 facing upward. Next, the wafer 4 is imaged from above with an imaging unit (not illustrated) of the cutting apparatus 18, and the projected dicing lines 6 are aligned in the X-axis direction in reference to the image of the wafer 4 captured by the imaging unit. Subsequently, while a cutting edge of the cutting blade 24 that is rotated at high speed in a direction indicated by an arrow R1 in FIG. 5 is caused to cut into the projected dicing lines 6 aligned in the X-axis direction to reach the reverse side 4b from the face side 4a and cutting water is being supplied to portions into which the cutting edge of the cutting blade 24 is caused to cut, the chuck table is processing fed in the X-axis direction. This forms a dicing groove 26 in the projected dicing line 6.

Next, the cutting blade 24 is indexing fed in the Y-axis direction by an amount of distance between the adjacent projected dicing lines 6 in the Y-axis direction. Thereafter, forming the dicing groove 26 and indexing feeding are alternately repeated, so that dicing grooves 26 are formed along all of the projected dicing lines 6 extending in a first direction. Then, the chuck table is rotated by 90 degrees, and forming the dicing groove 26 in the projected dicing lines 6 extending in a second direction perpendicular to the first direction and indexing feeding are alternately repeated. This forms dicing grooves 26 along all of the projected dicing lines 6 orthogonal to the projected dicing lines 6 in which the dicing grooves 26 have previously been formed. In this manner, the dicing grooves 26 are formed in a grid pattern along the projected dicing lines 6 in a grid pattern. Consequently, the wafer 4 can be diced (divided) into individual device chips 8.

The dicing step can also be performed with use of a laser processing apparatus 28 illustrated in FIG. 6. The laser processing apparatus 28 includes a chuck table (not illustrated) for holding under suction the wafer 4, a laser oscillator (not illustrated) that emits a pulsed laser beam LB of a wavelength absorbable by or transmittable through the wafer 4 to the wafer 4, and a light condenser 30 that condenses the pulsed laser beam LB emitted from the laser oscillator and applies the condensed laser beam LB to the wafer 4 held under suction on the chuck table.

When the dicing step is to be performed with use of the laser processing apparatus 28, first, the wafer 4 is held under suction on an upper surface of the chuck table with the face side 4a of the wafer 4 facing upward. Next, the wafer 4 is imaged from above by an imaging unit (not illustrated) of the laser processing apparatus 28, and the projected dicing lines 6 extending in the first direction are aligned in the X-axis direction in reference to the image of the wafer 4 captured by the imaging unit. Subsequently, the laser beam LB is focused on the projected dicing lines 6 aligned in the X-axis direction, and a focused spot of the laser beam LB is positioned on the face side 4a of the wafer 4. Note that the face side 4a is preferably covered in advance by a protective film such as water soluble resin so as to avoid any debris from adhering to the face side 4a of the wafer 4.

Next, while the chuck table is being processing fed in the X-axis direction, the laser beam LB of a wavelength absorbable by the wafer 4 is applied to the wafer 4 from the light condenser 30. As a result, ablation processing is applied to the face side 4a of the wafer 4, and a laser processing groove 32 that reaches the reverse side 4b from the face side 4a can be formed along the projected dicing line 6 extending in the first direction (see FIGS. 6 and 7A). Further, as in the case where the dicing grooves 26 are formed with use of the cutting apparatus 18, application of the laser beam LB and indexing feeding are alternately repeated, so that the laser processing grooves 32 in a grid pattern are formed on the face side 4a of the wafer 4 along the projected dicing lines 6 in a grid pattern.

When the wafer 4 is to be diced with use of the laser processing apparatus 28, as illustrated in FIG. 7B, modified layers 34 as initiating points for dicing may be formed inside the wafer 4 along the projected dicing lines 6. This is because, even in a case where the modified layers 34 are formed, at the time when the thermocompression bonding sheet 12 is radially expanded by an expanding unit 38 of a pickup apparatus 36 to be described later, cracks extend from the modified layers 34 as initiating points for dicing, and the wafer 4 can be diced into individual device chips 8. In other words, the dicing step of dicing the wafer 4 into individual device chips 8 may be performed by forming the modified layers 34 with use of the laser processing apparatus 28 and applying radial external force to the thermocompression bonding sheet 12. Note that, when the modified layers 34 are to be formed with use of the laser processing apparatus 28, a laser beam LB of a wavelength transmittable through the wafer 4 is applied to the wafer 4 along the projected dicing lines 6 with the focused spot of the laser beam LB being positioned inside the wafer 4.

### (Pickup Step)

In the present embodiment, after the dicing step is performed, a pickup step of picking up device chips 8 from the thermocompression bonding sheet 12 is carried out.

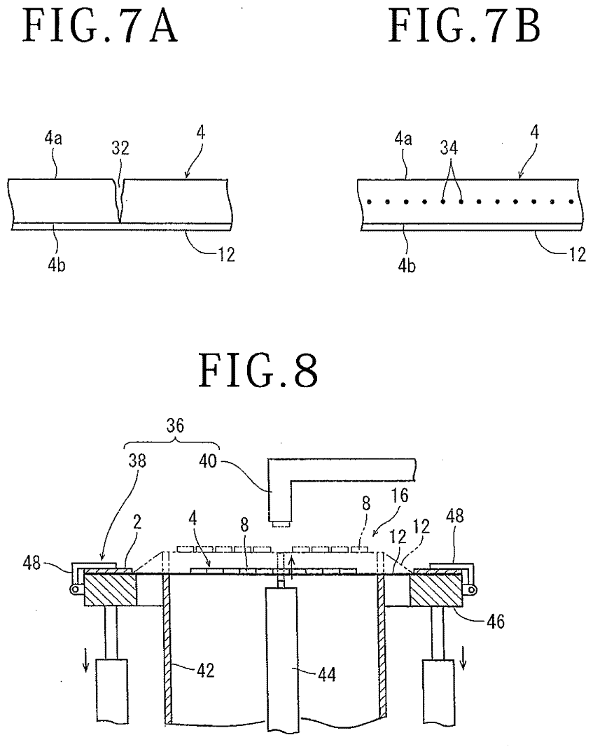

The pickup step can, for example, be performed with use of the pickup apparatus 36 illustrated in FIG. 8. The pickup apparatus 36 includes the expanding unit 38 that expands the thermocompression bonding sheet 12 and increases the distance between adjacent device chips 8 and a collet 40 for holding under attraction the device chips 8 and conveying the device chips 8. The expanding unit 38 includes a cylindrical drum 42, a pushing-up unit 44 that is disposed inside the drum 42 and used to push up the device chips 8, and an annular holding member 46 disposed on an outer periphery of the drum 42. On an outer peripheral edge of the holding member 46, a plurality of clamps 48 are disposed at spaced intervals along a circumferential direction. The collet 40 is connected to suction means (not illustrated) and holds under attraction the device chips 8 at a lower surface of the distal end.

In the pickup step, first, the annular frame 2 is placed on an upper surface of the holding member 46 with the wafer 4 facing upward. Next, the annular frame 2 is fixed by the plurality of clamps 48. Subsequently, the holding member 46 is lowered such that external force radially acts on the thermocompression bonding sheet 12. As a result, the distance between the device chips 8 on the thermocompression bonding sheet 12 is increased as illustrated by a dash double dot line illustrated in FIG. 8. Note that, in a case where the modified layers 34 are formed with use of the laser processing apparatus 28, when radial external force is applied to the thermocompression bonding sheet 12, the wafer 4 is divided into individual device chips 8, and the distance between the device chips 8 is increased.

Next, while the collet 40 is positioned above the device chip 8 that is to be picked up, the pushing-up unit 44 is positioned below the device chip 8 that is to be picked up. Subsequently, while the device chip 8 is being pushed up by the pushing-up unit 44, the collet 40 is lowered, and the device chip 8 is held under attraction by the lower surface of the distal end of the collet 40. Then, the collet 40 is raised, and the device chip 8 is picked up. Thereafter, the picked-up device chip 8 is conveyed to a predetermined position such as a tray. Repeating such pickup process allows all the device chips 8 to be conveyed from the thermocompression bonding sheet 12 of the frame unit 16.

As described above, in the present embodiment, since the frame unit 16 is formed with use of the thermocompression bonding sheet 12 that has no glue layer, the problem of glue scattering together with cutting water and sticking to the face sides of the devices 8 to eventually lower the quality of the device chips 8 when the wafer 4 is cut with the cutting blade 24 is resolved. Moreover, even when the dicing grooves (laser processing grooves 32) or the modified layers 34 as initiating points for dicing are formed by application of the laser beam LB to the projected dicing lines 6 in the wafer 4, since the thermocompression bonding sheet 12 has no glue layer, the problem of glue sticking to the devices 8 to cause lower quality of device chips 8 and to eventually become the source of contamination in the subsequent pickup step is resolved.

Further, according to the present embodiment, since plasma processing or corona treatment is applied to the surface of the thermocompression bonding sheet 12 on the side which is to be disposed on the wafer 4 and the annular frame 2 and the surface of the thermocompression bonding sheet 12 is activated, the adhesiveness of the thermocompression bonding sheet 12 with respect to the wafer 4 and the annular frame 2 is enhanced, and no water in which processing swarf generated during the dicing by the cutting blade 24 is mixed would enter any portion between the thermocompression bonding sheet 12 and the wafer 4. As a result, lowered quality of the device chips 8 is prevented.

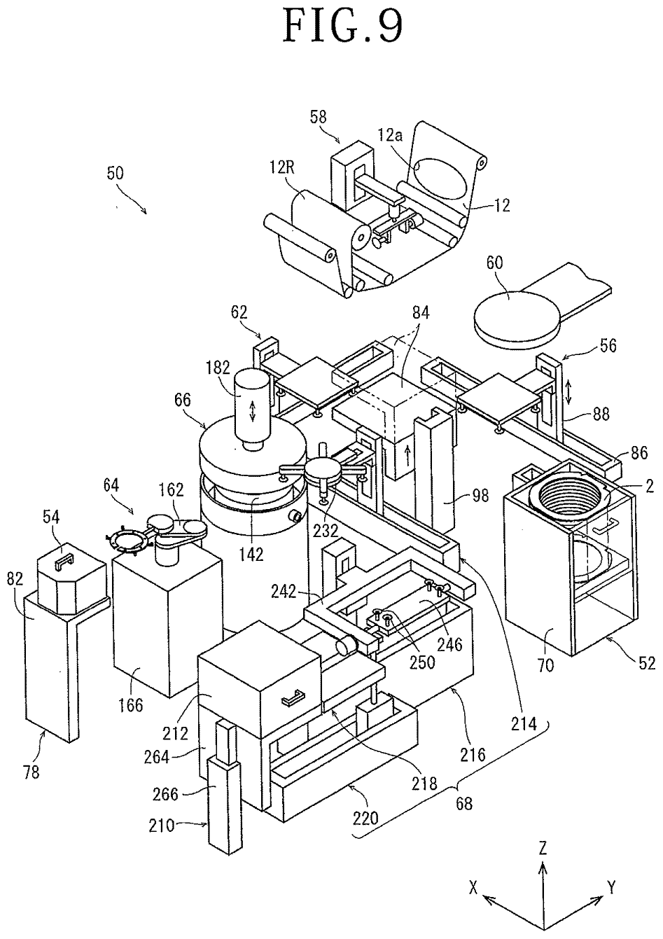

Next, a preferred embodiment of a frame unit forming apparatus according to the present invention will be explained with reference to FIGS. 9 through 20.

The frame unit forming apparatus denoted by 50 and illustrated in FIG. 9 includes a frame housing unit 52, a wafer housing unit 54, a frame conveying mechanism 56, a thermocompression bonding sheet disposing unit 58, an activation unit 60, a frame sheet conveying mechanism 62, a wafer unloading mechanism 64, a frame unit forming mechanism 66, and a cassette housing unit 68.

### (Frame Housing Unit 52)

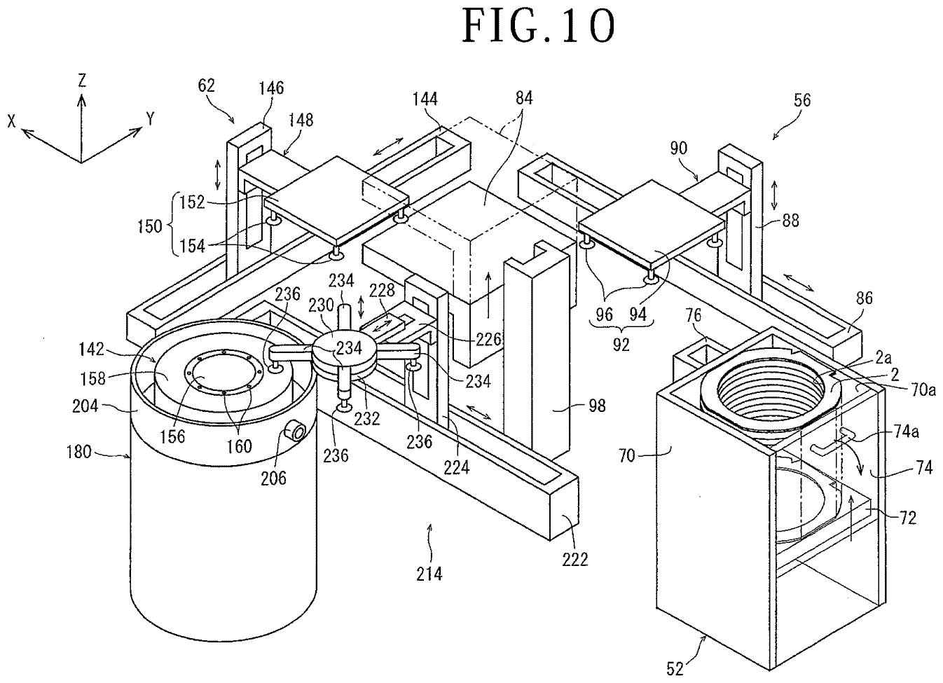

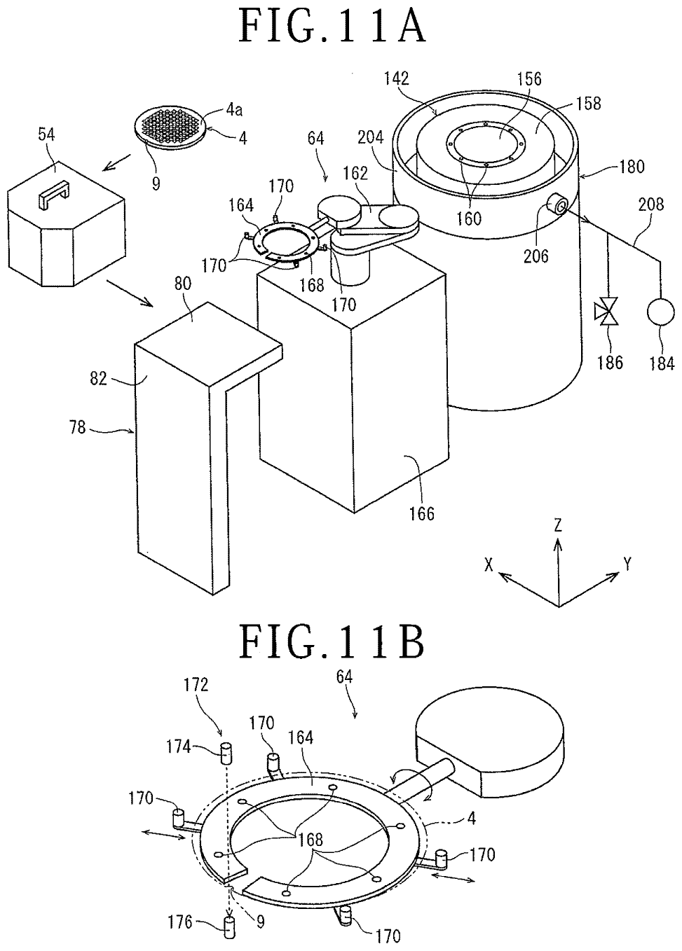

The frame housing unit 52 houses a plurality of annular frames 2 each having, at its center, the opening portion 2a for housing the wafer 4. As illustrated in FIG. 10, the frame housing unit 52 according to the present embodiment includes a housing 70 and a lifting and lowering plate 72 disposed to be liftable and lowerable inside the housing 70.

On a lateral surface of the housing 70 on the near side in the X-axis direction in FIG. 10, a door 74 to which a handle 74a is attached is provided. In the frame housing unit 52, when the door 74 is opened with the handle 74a gripped, the annular frame 2 can be housed inside the housing 70. Further, an opening portion 70a is provided on an upper end of the housing 70.

An X-axis direction in the present embodiment is a direction indicated by an arrow X illustrated in FIG. 10. A Y-axis direction indicated by an arrow Y in FIG. 10 is a direction perpendicular to the X-axis direction, and a Z-axis direction indicated by an arrow Z in FIG. 10 is a vertical direction perpendicular to both the X-axis direction and the Y-axis direction. An XY plane defined by the X-axis direction and the Y-axis direction is substantially horizontal.

On a lateral surface of the housing 70 on the far side in the X-axis direction in FIG. 10, a Z-axis guide member 76 extending in the Z-axis direction is provided. On the Z-axis guide member 76, the abovementioned lifting and lowering plate 72 is supported in a liftable and lowerable manner. Further, inside the Z-axis guide member 76, a lifting and lowering mechanism (not illustrated) which may be of a ball screw type for lifting and lowering the lifting and lowering plate 72 is disposed.

As illustrated in FIG. 10, the annular frames 2 are housed by being stacked on an upper surface of the lifting and lowering plate 72 inside the housing 70. The uppermost annular frame 2 among the plurality of annular frames 2 being stacked is conveyed by the frame conveying mechanism 56 from the opening portion 70a of the housing 70. When the annular frame 2 is unloaded from the opening portion 70a of the housing 70, the frame housing unit 52 lifts the lifting and lowering plate 72 by the lifting and lowering mechanism as appropriate to position the uppermost annular frame 2 at a position where the annular frame 2 can be conveyed by the frame conveying mechanism 56.

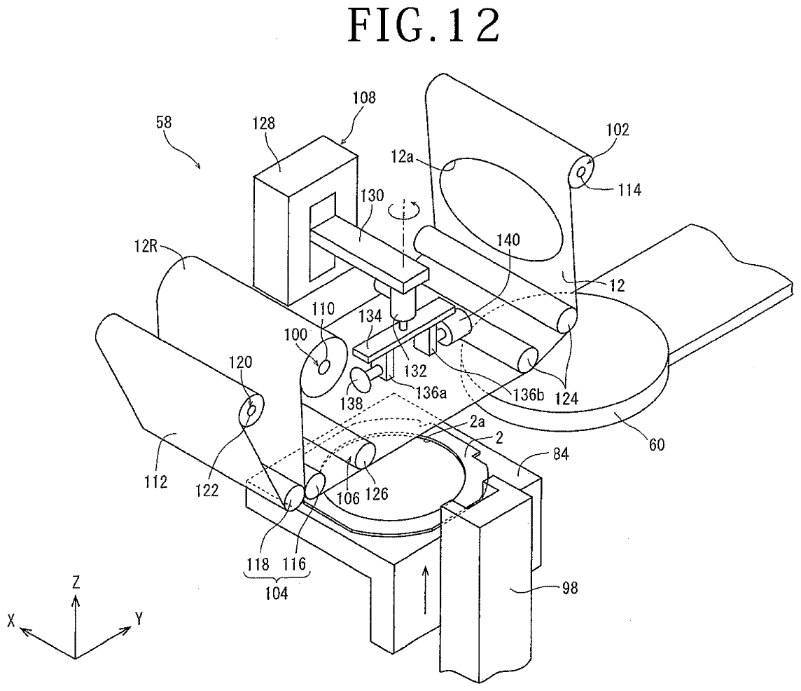

The wafer housing unit 54 houses a plurality of wafers 4. As illustrated in FIG. 11A, the wafer housing unit 54 according to the present embodiment is a cassette that houses a plurality of wafers 4 at spaced intervals in the vertical direction in a state in which the face side 4a of each of the wafers 4 is facing upward. Further, the wafer housing unit 54 is supported on a cassette table 78. The cassette table 78 includes a top plate 80 on which the wafer housing unit 54 is placed and a support plate 82 that supports the top plate 80. Note that the top plate 80 is liftable and lowerable, and a lifting and lowering mechanism that lifts and lowers the top plate 80 to position the top plate 80 at a desired height may be provided in the cassette table 78.

Described with reference to FIG. 10, the frame conveying mechanism 56 unloads the annular frame 2 from the frame housing unit 52 and places the unloaded annular frame 2 on a frame table 84. The frame conveying mechanism 56 includes an X-axis guide member 86 extending in the X-axis direction, an X-axis movable member 88 supported by the X-axis guide member 86 in a movable manner in the X-axis direction, an X-axis feeding mechanism (not illustrated) which may be of a ball screw type for moving the X-axis movable member 88 in the X-axis direction, a Z-axis movable member 90 supported by the X-axis movable member 88 in a movable manner in the Z-axis direction, and Z-axis feeding means (not illustrated) which may be of a ball screw type for moving the Z-axis movable member 90 in the Z-axis direction. The Z-axis movable member 90 has a holding section 92 for holding the annular frame 2. The holding section 92 includes a rectangular board 94 and a plurality of suction pads 96 provided on a lower surface of the board 94, and each of the suction pads 96 is connected to suction means (not illustrated).

The frame conveying mechanism 56 moves the X-axis movable member 88 and the Z-axis movable member 90 after holding under suction the uppermost annular frame 2 housed in the frame housing unit 52 by the suction pads 96 of the holding section 92, to unload from the frame housing unit 52 the uppermost annular frame 2 held under suction and place it on the frame table 84.

The frame table 84 is supported by the Z-axis guide member 98 in a liftable and lowerable manner. To the Z-axis guide member 98, an appropriate drive source (for example, an air drive source or an electric drive source) that lifts and lowers the frame table 84 is attached. The frame table 84 is configured to receive the annular frame 2 unloaded by the frame conveying mechanism 56, at a delivery position illustrated by a solid line in FIG. 10. Moreover, in the frame table 84, an electric heater and a temperature sensor (neither of which is illustrated) are incorporated, and the temperature of an upper surface of the frame table 84 is adjusted by an appropriate control apparatus.

The thermocompression bonding sheet disposing unit 58 disposes the thermocompression bonding sheet 12 on the annular frame 2 placed on the frame table 84. As illustrated in FIG. 12, the thermocompression bonding sheet disposing unit 58 includes a rolled sheet support section 100 that supports a rolled sheet 12R around which an unused thermocompression bonding sheet 12 is wound, a sheet winding section 102 that winds up the used thermocompression bonding sheet 12, a sheet drawing section 104 that draws the thermocompression bonding sheet 12 from the rolled sheet 12R, a thermocompression bonding section 106 that thermocompression-bonds the drawn thermocompression bonding sheet 12 to the annular frame 2, and a cutting section 108 that cuts, along the annular frame 2, the thermocompression bonding sheet 12 sticking out from the outer periphery of the annular frame 2.

The rolled sheet support section 100 includes a support roller 110 supported by an appropriate bracket (not illustrated) in a rotatable manner about an axis line extending in the X-axis direction. On the support roller 110, supported is the rolled sheet 12R around which peeling paper 112 for protecting the thermocompression bonding surface of the thermocompression bonding sheet 12 is cylindrically wound by being attached to the thermocompression bonding surface of the thermocompression bonding sheet 12.

The sheet winding section 102 includes a winding roller 114 supported by an appropriate bracket (not illustrated) in a rotatable manner about an axis line extending in the X-axis direction and a motor (not illustrated) for rotating the winding roller 114. The sheet winding section 102 rotates the winding roller 114 by the motor and winds up the used thermocompression bonding sheet 12 in which a circular opening portion 12a corresponding to the portion that has been thermocompression-bonded to the annular frame 2 is formed.

The sheet drawing section 104 includes a drawing roller 116 disposed on a lower side of the support roller 110 of the rolled sheet support section 100, a motor (not illustrated) for rotating the drawing roller 116, and a driven roller 118 that rotates in association with the rotation of the drawing roller 116. The sheet drawing section 104 rotates the drawing roller 116 and the driven roller 118 by the motor, and draws, from the rolled sheet 12R, the thermocompression bonding sheet 12 sandwiched by the drawing roller 116 and the driven roller 118.

From the thermocompression bonding sheet 12 that has passed between the drawing roller 116 and the driven roller 118, the peeling paper 112 is peeled off, and the peeling paper 112 that has been peeled off is wound up by a peeling paper winding section 120. The peeling paper winding section 120 includes a peeling paper winding roller 122 disposed on the upper side of the driven roller 118 and a motor (not illustrated) for rotating the peeling paper winding roller 122. The thermocompression bonding sheet 12 from which the peeling paper 112 has been peeled off is guided to the winding roller 114 through a pair of guide rollers 124 disposed with some space from the drawing roller 116 in the Y-axis direction. In the present embodiment, the peeling paper 112 is attached to the thermocompression bonding sheet 12, but the peeling paper 112 may not be provided to the thermocompression bonding sheet 12, and in this case, the peeling paper winding roller 122 need not be provided.

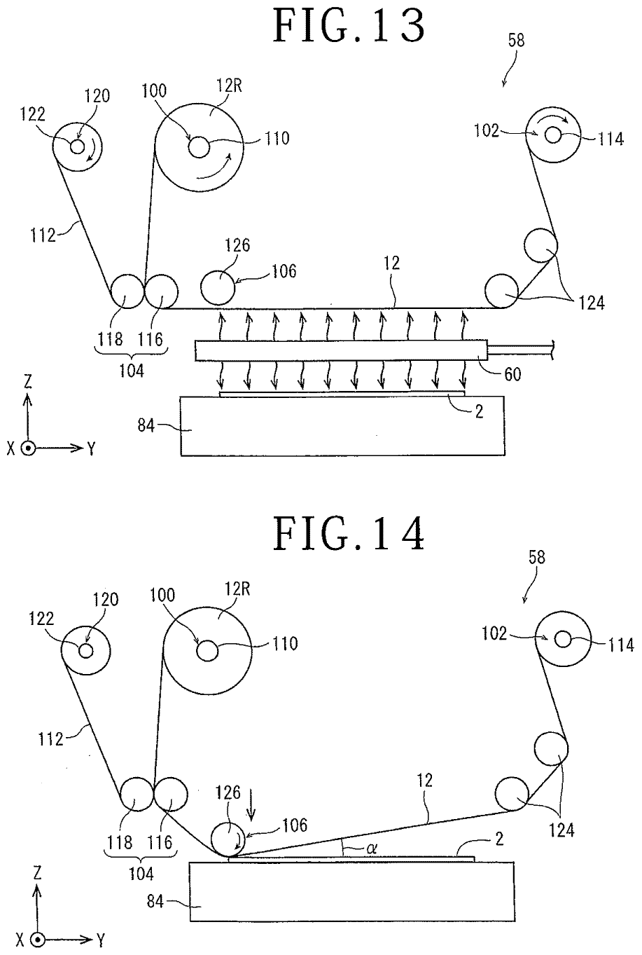

The thermocompression bonding section 106 includes a heating roller 126 disposed in a movable manner in the Y-axis direction, a lifting and lowering mechanism (not illustrated) which may be of a ball screw type for lifting and lowering the heating roller 126, and a Y-axis feeding mechanism (not illustrated) which may be of a ball screw type for moving the heating roller 126 in the Y-axis direction. In the heating roller 126, an electric heater and a temperature sensor (neither of which is illustrated) are incorporated, and the temperature of an outer peripheral surface of the heating roller 126 is adjusted by an unillustrated control apparatus. The outer peripheral surface of the heating roller 126 is coated with fluorine resin, and hence, the thermocompression bonding sheet 12 does not stick to the heating roller 126 even when exhibiting adhesion. The lifting and lowering mechanism of the thermocompression bonding section 106 positions the heating roller 126 at an upper side waiting position illustrated in FIG. 13 and a lower side pressing position illustrated in FIG. 14. The Y-axis feeding mechanism of the thermocompression bonding section 106 moves the heating roller 126 in the Y-axis direction in a state in which the heating roller 126 is positioned at the lower side pressing position.

The cutting section 108 includes a Z-axis guide member 128 extending in the Z-axis direction, a Z-axis movable member 130 supported by the Z-axis guide member 128 in a movable manner in the Z-axis direction, and Z-axis feeding means (not illustrated) which may be of a ball screw type for moving the Z-axis movable member 130 in the Z-axis direction. Moreover, the cutting section 108 includes a motor 132 fixed to a lower surface of a distal end of the Z-axis movable member 130 and an arm piece 134 that is rotated by the motor 132 about an axis line extending in the Z-axis direction. To a lower surface of the arm piece 134, first and second hanging pieces 136a and 136b are attached with a space between each other. On the first hanging piece 136a, a circular cutter 138 is supported rotatably about an axis line perpendicular to the Z-axis direction, while on the second hanging piece 136b, a pressing roller 140 is supported rotatably about an axis line perpendicular to the Z-axis direction.

The thermocompression bonding sheet disposing unit 58 draws an unused thermocompression bonding sheet 12 by the drawing roller 116 and the driven roller 118 before the frame table 84 that has received the annular frame 2 from the frame conveying mechanism 56 is positioned to a thermocompression bonding start position (the position illustrated in FIG. 14) from the delivery position (the position illustrated in FIG. 13). Next, the thermocompression bonding sheet disposing unit 58 lifts the frame table 84 to the thermocompression bonding start portion, and also lowers the heating roller 126 to the lower side pressing position. Subsequently, while pressing the thermocompression bonding sheet 12 downward by the heating roller 126 adjusted to a temperature at which the thermocompression bonding sheet 12 exhibits adhesion by softening or melting, the thermocompression bonding sheet disposing unit 58 rolls the heating roller 126 in the Y-axis direction. As a result, the thermocompression bonding sheet 12 is heated to exhibit adhesion, and can thus be thermocompression-bonded to the annular frame 2.

After the thermocompression bonding sheet 12 is thermocompression-bonded to the annular frame 2, the thermocompression bonding sheet disposing unit 58 lowers the Z-axis movable member 130 of the cutting section 108 and presses the cutter 138 against the thermocompression bonding sheet 12 on the annular frame 2 while pressing the annular frame 2 over the thermocompression bonding sheet 12 by the pressing roller 140. Next, the thermocompression bonding sheet disposing unit 58 rotates the arm piece 134 by the motor 132 and moves the cutter 138 and the pressing roller 140 such that a circle is drawn along the annular frame 2. As a result, the thermocompression bonding sheet 12 sticking out from the outer periphery of the annular frame 2 can be cut along the annular frame 2. Moreover, since the annular frame 2 is pressed over the thermocompression bonding sheet 12 by the pressing roller 140, the annular frame 2 and the thermocompression bonding sheet 12 are prevented from being misaligned at the time when the thermocompression bonding sheet 12 is cut. Subsequently, after the frame table 84 is lowered, the used thermocompression bonding sheet 12 in which the circular opening portion 12a corresponding to a portion that has been thermocompression-bonded to the annular frame 2 is formed is wound up by the sheet winding section 102.

The activation unit 60 applies plasma processing or corona treatment to the thermocompression bonding sheet 12 on the side which is to be disposed on the annular frame 2 by the thermocompression bonding sheet disposing unit 58. Described with reference to FIG. 12, the activation unit 60 according to the present embodiment is configured to be movable in the Y-axis direction. When being positioned to the acting position between the thermocompression bonding sheet 12 drawn by the sheet drawing section 104 of the thermocompression bonding sheet disposing unit 58 and the annular frame 2 on the frame table 84, the activation unit 60 applies plasma processing or corona treatment to the thermocompression bonding sheet 12 and activates the thermocompression bonding sheet 12. This can improve the wettability of the surface of the thermocompression bonding sheet 12 on the side which is to be disposed on the annular frame 2. Note that the processing to be applied by the activation unit 60 may be atmospheric plasma processing.

The activation unit 60 preferably applies plasma processing or corona treatment also to the surface of the annular frame 2 on the side which is to be disposed on the thermocompression bonding sheet 12 (the upper surface of the annular frame 2 placed on the frame table 84) and activates the surface of the annular frame 2. This can also improve the wettability of the surface of the annular frame 2 on the side which is to be disposed on the thermocompression bonding sheet 12.

The frame sheet conveying mechanism 62 conveys the annular frame 2 on which the thermocompression bonding sheet 12 is disposed (sometimes referred to as a “frame sheet 2′” hereinbelow) to the frame unit forming table 142. As illustrated in FIG. 10, the frame sheet conveying mechanism 62 includes a Y-axis guide member 144 extending in the Y-axis direction, a Y-axis movable member 146 supported by the Y-axis guide member 144 in a movable manner in the Y-axis direction, a Y-axis feeding mechanism (not illustrated) which may be of a ball screw-type for moving the Y-axis movable member 146 in the Y-axis direction, a Z-axis movable member 148 supported by the Y-axis movable member 146 in a movable manner in the Z-axis direction, and Z-axis feeding means (not illustrated) which may be of a ball screw type for moving the Z-axis movable member 148 in the Z-axis direction. The Z-axis movable member 148 has a holding section 150 that holds the frame sheet 2′. The holding section 150 includes a rectangular board 152 and a plurality of suction pads 154 provided on a lower surface of the board 152. Each of the suction pads 154 is connected to suction means (not illustrated).

The frame sheet conveying mechanism 62 holds under suction, by the suction pads 154 of the holding section 150, an upper surface of the frame sheet 2′ supported on the frame table 84 and moves the Y-axis movable member 146 and the Z-axis movable member 148, to convey the frame sheet 2′ held under suction by the holding section 150 from the frame table 84 to the frame unit forming table 142.

As illustrated in FIG. 10, the frame unit forming table 142 includes a circular wafer supporting portion 156 that supports the wafer 4 and an annular frame supporting portion 158 that is arranged on an outer periphery of the wafer supporting portion 156 and that supports the annular frame 2. On a peripheral edge of an upper surface of the wafer supporting portion 156, a plurality of suction holes 160 disposed at spaced intervals in the circumferential direction are formed, and each of the suction holes 160 is connected to suction means (not illustrated). Moreover, in the wafer supporting portion 156, an electric heater and a temperature sensor (neither of which is illustrated) are incorporated. The temperature of an upper surface of the wafer supporting portion 156 is adjusted by an appropriate control apparatus.

Described with reference to FIG. 11A, the wafer unloading mechanism 64 unloads the wafer 4 from the wafer housing unit 54 and conveys the unloaded wafer 4 to the frame unit forming table 142. The wafer unloading mechanism 64 includes a conveying arm 162 and a hand 164 that is disposed on a distal end of the conveying arm 162 and supports the wafer 4 housed in the wafer housing unit 54.

The conveying arm 162 is provided on an upper surface of a base 166 and is driven by an appropriate drive source (not illustrated) such as an air drive source or an electric drive source. This drive source drives the conveying arm 162 and positions the hand 164 at a desired position in each of the X-axis direction, the Y-axis direction, and the Z-axis direction while turning the hand 164 upside down.

The hand 164 is preferably a Bernoulli pad in which negative pressure is generated by ejection of air to support the wafer 4 in a non-contact manner. As illustrated in FIG. 11B, the hand 164 according to the present embodiment has a C-shape in whole and has, on one surface, a plurality of air ejection ports 168 that are connected to a compressed air supply source (not illustrated). To an outer peripheral edge of the hand 164, a plurality of guide pins 170 are attached at spaced intervals in the circumferential direction. The guide pins 170 are configured to be movable in a radial direction of the hand 164.

The wafer unloading mechanism 64, after positioning the hand 164 to the reverse side 4b (lower side) of the wafer 4 inside the wafer housing unit 54, ejects compressed air from the air ejection ports 168 of the hand 164 and generates negative pressure on the one surface side of the hand 164 by the Bernoulli effect, to support under suction the wafer 4 from the reverse side 4b by the hand 164 in a non-contact manner. The horizontal movement of the wafer 4 supported under suction on the hand 164 is restricted by the guide pins 170. Further, the wafer unloading mechanism 64 moves the conveying arm 162 to unload the wafer 4 supported under suction by the hand 164 from the wafer housing unit 54 and convey the unloaded wafer 4 to the frame unit forming table 142.

The wafer unloading mechanism 64 includes a notch detecting unit 172 that detects the position of the notch 9 of the wafer 4. The notch detecting unit 172 may include, for example, a light emitting element 174 and a light receiving element 176 that are disposed with a space between each other in the vertical direction and a drive source (not illustrated) that rotates at least one of the guide pins 170 of the hand 164. The light emitting element 174 and the light receiving element 176 can be arranged on a conveying route of the conveying arm 162 via an appropriate bracket (not illustrated). When the guide pins 170 rotate by the drive source, the rotation of the guide pins 170 rotates the wafer 4 supported under suction by the hand 164. In order to reliably transmit the rotation of the guide pins 170 to the wafer 4, an outer peripheral surface of each of the guide pins 170 that rotate by the drive source is preferably formed with appropriate synthetic rubber.

The notch detecting unit 172 can detect the position of the notch 9 by rotating the wafer 4 via the guide pins 170 by the drive source, in a state in which the wafer 4 is supported under suction by the hand 164 and the outer periphery of the wafer 4 is positioned between the light emitting element 174 and the light receiving element 176. This makes it possible to adjust the orientation of the wafer 4 to a desired orientation.

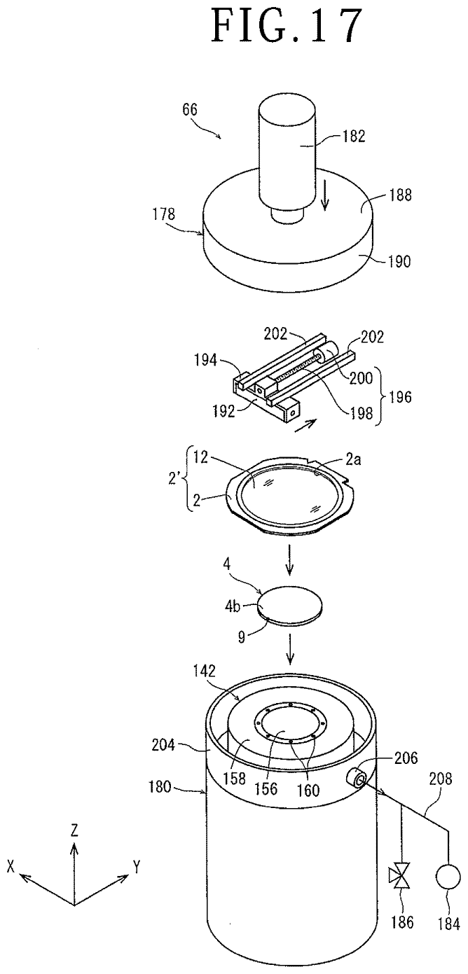

Described with reference to FIG. 17, the frame unit forming mechanism 66 forms the frame unit 16 by integrating the wafer 4 with the frame sheet 2′ (the annular frame 2 on which the thermocompression bonding sheet 12 is disposed) that has been conveyed to the frame unit forming table 142. The frame unit forming mechanism 66 includes an upper chamber 178 disposed above the frame unit forming table 142, a lower chamber 180 in which the frame unit forming table 142 is housed, a lifting and lowering mechanism 182 that lifts and lowers the upper chamber 178 to establish a closed state in which the upper chamber 178 is in contact with the lower chamber 180 and an open state in which the upper chamber 178 is separated from the lower chamber 180, a vacuum section 184 that vacuums the upper chamber 178 and the lower chamber 180 in the closed state, and an atmospheric opening section 186 that opens the upper chamber 178 and the lower chamber 180 to atmospheric air.

The upper chamber 178 includes a circular top plate 188 and a cylindrical sidewall 190 hanging down from a peripheral edge of the top plate 188. On an upper surface of the top plate 188, the lifting and lowering mechanism 182 that can be configured with an appropriate actuator such as an air cylinder is mounted. Disposed inside a housing space defined by a lower surface of the top plate 188 and an inner peripheral surface of the sidewall 190 are a heating roller 192 for thermocompression-bonding the thermocompression bonding sheet 12 of the frame sheet 2′ to one surface of the wafer 4 supported by the frame unit forming table 142, a support piece 194 that supports the heating roller 192 in a rotatable manner, and a Y-axis feeding mechanism 196 that moves the support piece 194 in the Y-axis direction.

In the heating roller 192, an electric heater and a temperature sensor (neither of which is illustrated) are incorporated, and the temperature of an outer peripheral surface of the heating roller 192 is adjusted by an unillustrated control apparatus. The outer peripheral surface of the heating roller 192 is coated with fluorine resin, and hence, the thermocompression bonding sheet 12 does not stick to the heating roller 192 even when exhibiting adhesion.

The Y-axis feeding mechanism 196 includes a ball screw 198 coupled to the support piece 194 and extending in the Y-axis direction and a motor 200 for rotating the ball screw 198. The Y-axis feeding mechanism 196 converts the rotational motion of the motor 200 into linear motion by the ball screw 198 and transmits the linear motion to the support piece 194, to move the support piece 194 in the Y-axis direction along a pair of guide rails 202 extending in the Y-axis direction.

The lower chamber 180 includes a cylindrical sidewall 204 an upper portion of which is open and a lower portion of which is closed. A connection opening 206 is formed in the sidewall 204. To the connection opening 206, the vacuum section 184 that can be configured by an appropriate vacuum pump is connected via a flow channel 208. In the flow channel 208, the atmospheric opening section 186 that can be configured by an appropriate valve capable of opening the flow channel 208 to atmospheric air is provided.

The frame unit forming mechanism 66 lowers the upper chamber 178 by the lifting and lowering mechanism 182 and brings a lower end of the sidewall 190 of the upper chamber 178 into contact with an upper end of the sidewall 204 of the lower chamber 180 to establish a closed state between the upper chamber 178 and the lower chamber 180, while bringing the heating roller 192 into contact with the frame sheet 2′, in a state in which the thermocompression bonding sheet 12 of the frame sheet 2′ is positioned on the one surface of the wafer 4 supported by the frame unit forming table 142.

Next, the frame unit forming mechanism 66 operates the vacuum pump configuring the vacuum section 184 in a state in which the valve configuring the atmospheric opening section 186 is closed, and vacuums the inside of the upper chamber 178 and the lower chamber 180. Subsequently, the temperature of the heating roller 192 is adjusted to a temperature at which the thermocompression bonding sheet 12 exhibits adhesion by softening or melting. Then, the heating roller 192 is rolled in the Y-axis direction by the Y-axis feeding mechanism 196. As a result, the thermocompression bonding sheet 12 is heated to exhibit adhesion, and can thus be thermocompression-bonded to the one surface of the wafer 4. As a result, the frame unit 16 is formed.

According to the present embodiment, the thermocompression bonding sheet 12 is thermocompression-bonded to the wafer 4 in a state in which the inside of the upper chamber 178 and the lower chamber 180 is vacuumed, and hence, when the atmospheric opening section 186 is opened after the thermocompression bonding sheet 12 is thermocompression-bonded to the wafer 4, the thermocompression bonding sheet 12 is pressed against the wafer 4 by atmospheric pressure. This enhances the adhesiveness between the thermocompression bonding sheet 12 and the wafer 4.

Described with reference to FIG. 9, the cassette housing unit 68 houses the frame units 16 formed by the frame unit forming mechanism 66 in a cassette 212 placed on a cassette table 210. The cassette housing unit 68 includes frame unit unloading means 214 that unloads the frame unit 16 formed by the frame unit forming mechanism 66 from the frame unit forming table 142, an inverting mechanism 216 that turns upside down the frame unit 16 unloaded by the frame unit unloading means 214, a frame unit supporting section 218 that supports the frame unit 16 that has been turned upside down by the inverting mechanism 216 and that has the face side 4a of the wafer 4 facing upward, and a pushing-in section 220 that causes the frame unit 16 supported by the frame unit supporting section 218 to move into the cassette 212 placed on the cassette table 210 and to be housed therein.

As illustrated in FIG. 10, the frame unit unloading means 214 includes an X-axis guide member 222 extending in the X-axis direction, an X-axis movable member 224 supported by the X-axis guide member 222 in a movable manner in the X-axis direction, an X-axis feeding mechanism (not illustrated) which may be of a ball screw type for moving the X-axis movable member 224 in the X-axis direction, a Z-axis movable member 226 supported by the X-axis movable member 224 in a movable manner in the Z-axis direction, Z-axis feeding means (not illustrated) which may be of a ball screw type for moving the Z-axis movable member 226 in the Z-axis direction, a Y-axis movable member 228 supported by the Z-axis movable member 226 in a movable manner in the Y-axis direction, and a Y-axis feeding mechanism (not illustrated) which may be of a ball screw type for moving the Y-axis movable member 228 in the Y-axis direction.

To the Y-axis movable member 228 of the frame unit unloading means 214, a circular board 230 is mounted. On a lower surface of the board 230, a wafer activation unit 232 that applies plasma processing or corona treatment to the wafer 4 conveyed to the frame unit forming table 142 is provided. On a peripheral edge of the board 230, a plurality of (four in the illustrated embodiment) projecting pieces 234 that project outward in a radial direction are provided at spaced intervals in the circumferential direction. On a lower surface of each of the projecting pieces 234, a suction pad 236 is arranged, and each of the suction pads 236 is connected to suction means (not illustrated).

In the frame unit unloading means 214, after the wafer 4 has been conveyed to the frame unit forming table 142 but before the frame sheet 2′ is conveyed to the frame unit forming table 142, the X-, Y-, and Z-axis movable members 224, 228, and 226 are moved, to position the wafer activation unit 232 above the wafer 4 placed on the frame unit forming table 142. The wafer activation unit 232 applies plasma processing or corona treatment to the wafer 4 and activates the wafer 4. This improves the wettability of the surface of the wafer 4 on the side which is to be disposed on the thermocompression bonding sheet 12. Note that the processing to be applied by the wafer activation unit 232 may be atmospheric plasma processing.

Moreover, the frame unit unloading means 214, after plasma processing or corona treatment has been applied to the wafer 4, separates away from the upper side of the frame unit forming table 142. Further, after the frame unit 16 is formed, the frame unit unloading means 214 holds under suction, by the suction pads 236, the upper surface of the annular frame 2 of the frame unit 16 supported on the frame unit forming table 142 and moves the X-, Y-, and Z-axis movable members 224, 228, and 226, to unload the frame unit 16 held under suction by the suction pads 236 from the frame unit forming table 142.

As illustrated in FIG. 18, the inverting mechanism 216 includes a Y-axis guide member 238 extending in the Y-axis direction, a Y-axis movable member 240 supported by the Y-axis guide member 238 in a movable manner in the Y-axis direction, a Y-axis feeding mechanism (not illustrated) which may be of a ball screw type for moving the Y-axis movable member 240 in the Y-axis direction, an arm 242 supported by the Y-axis movable member 240 in a movable manner in the Z-axis direction, and Z-axis feeding means (not illustrated) which may be of a ball screw type for moving the arm 242 in the Z-axis direction. On the arm 242, a board 246 is supported in a rotatable manner via a pair of rotational shafts 244. Coupled to one of the rotational shafts 244 is a motor 248 that turns the board 246 upside down. On one surface of the board 246, a plurality of suction pads 250 are provided, and each of the suction pads 250 is connected to suction means (not illustrated).

The inverting mechanism 216 holds under suction, by the suction pads 250, the lower surface of the annular frame 2 of the frame unit 16 held by the frame unit unloading means 214 in a state in which the suction pads 250 are facing upward, and receives the frame unit 16 from the frame unit unloading means 214. Further, after turning the board 246 upside down by the motor 248 and making the face side 4a of the wafer 4 face upward, the inverting mechanism 216 moves the Y-axis movable member 240 to move the frame unit 16 held under suction by the suction pads 250 toward the cassette table 210.

### (Frame Unit Supporting Section 218)

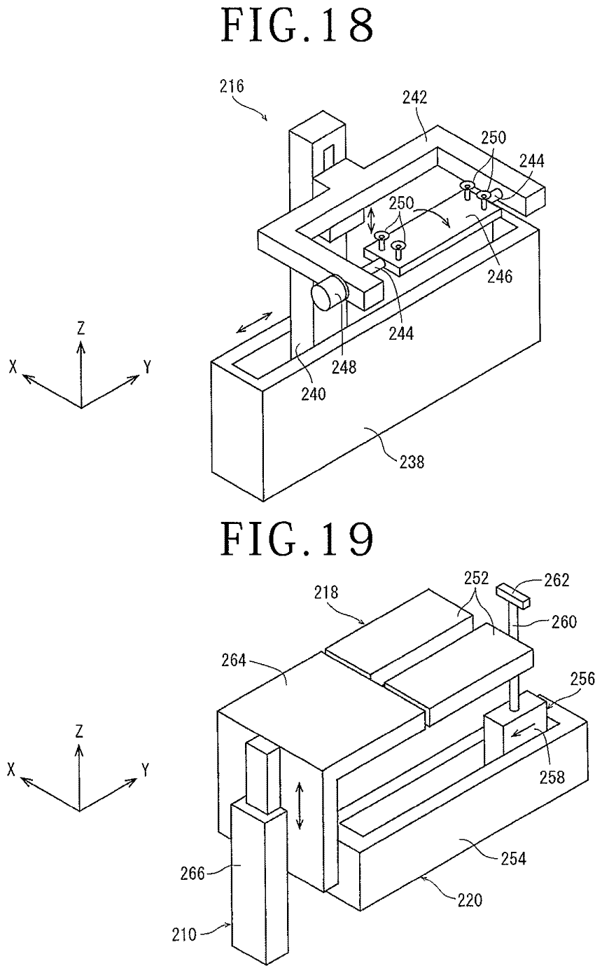

As illustrated in FIG. 19, the frame unit supporting section 218 includes a pair of support plates 252 arranged with a space therebetween in the X-axis direction. The pair of support plates 252 are fixed by an appropriate bracket (not illustrated).

The pushing-in section 220 includes a Y-axis guide member 254 extending in the Y-axis direction, a Y-axis movable member 256 supported by the Y-axis guide member 254 in a movable manner in the Y-axis direction, and a Y-axis feeding mechanism (not illustrated) which may be of a ball screw type for moving the Y-axis movable member 256 in the Y-axis direction. The Y-axis movable member 256 includes a base portion 258 supported by the Y-axis guide member 254, a support column 260 extending upward from an upper surface of the base portion 258, and a pressing piece 262 attached to an upper end of the support column 260.

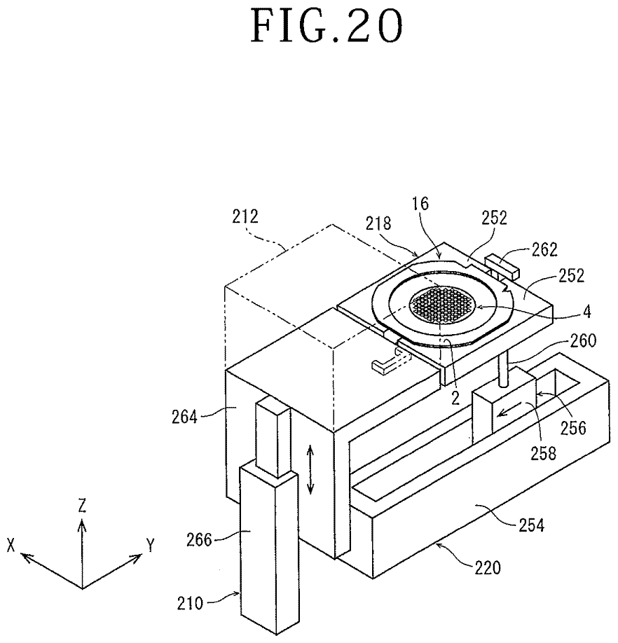

As illustrated in FIG. 20, the frame unit supporting section 218 receives the frame unit 16 held by the suction pads 250 of the inverting mechanism 216. When the frame unit supporting section 218 receives the frame unit 16, the pushing-in section 220 moves the Y-axis movable member 256 in the Y-axis direction by the Y-axis feeding mechanism, to cause the frame unit 16 supported by the frame unit supporting section 218 to enter the cassette 212 placed on the cassette table 210 and to be housed therein by the pressing piece 262.

In the cassette 212, a plurality of pieces of frame units 16 are housed at spaced intervals in the vertical direction. As illustrated in FIGS. 19 and 20, the cassette table 210 includes a placing portion 264 on which the cassette 212 is placed and a lifting and lowering unit 266 which may be of a ball screw type for lifting and lowering the placing portion 264 and positioning the placing portion 264 at a desired height.

Next, a method of housing the wafer 4 in the opening portion 2a of the annular frame 2 and forming the frame unit 16 by the thermocompression bonding sheet 12 with use of the frame unit forming apparatus 50 as described above will be explained.

### (Wafer Setting Step)

According to the present embodiment, first, as illustrated in FIG. 11A, a wafer setting step of setting the wafer housing unit 54 in which a plurality of wafer 4 are housed to a cassette table 78 is carried out. In the wafer housing unit 54, a plurality of pieces of wafers 4 are housed at spaced intervals in the vertical direction with the face sides 4a facing upward.

### (Frame Housing Step)

Next, as illustrated in FIGS. 9 and 10, a frame housing step of housing a plurality of annular frames 2 in the frame housing unit 52 is carried out. In the frame housing step, after the lifting and lowering plate 72 of the frame housing unit 52 is lowered to a desired position, the handle 74a is gripped to open the door 74, and the plurality of annular frames 2 are housed by being stacked on the upper surface of the lifting and lowering plate 72. Further, the height of the lifting and lowering plate 72 is adjusted as appropriate, and the uppermost annular frame 2 is positioned at a position where the annular frame 2 can be conveyed by the frame conveying mechanism 56. Note that the frame housing step may be performed either before or after the wafer setting step.

### (Wafer Unloading Step)

After the wafer setting step and the frame housing step are performed, a wafer unloading step of unloading the wafer 4 from the wafer housing unit 54 and conveying the unloaded wafer 4 to the frame unit forming table 142 is carried out.

Described with reference to FIG. 11B, in the wafer unloading step, first, the conveying arm 162 of the wafer unloading mechanism 64 is driven to position the hand 164, with the air ejection ports 168 facing upward, on the reverse side 4b (lower side) of the wafer 4 in the wafer housing unit 54. When the hand 164 is positioned on the reverse side 4b of the wafer 4, a gap should be provided between the reverse side 4b of the wafer 4 and the hand 164, and the guide pins 170 should be positioned outward in the radial direction. Next, compressed air is ejected from the air ejection ports 168 of the hand 164 and negative pressure is generated on the one surface side of the hand 164 by the Bernoulli effect, so that the wafer 4 is supported under suction from the reverse side 4b in a non-contact manner by the hand 164. Subsequently, the guide pins 170 are moved inward in the radial direction, to restrict the horizontal movement of the wafer 4 supported under suction by the hand 164. Then, the conveying arm 162 of the wafer unloading mechanism 64 is moved, and the wafer 4 supported under suction by the hand 164 is unloaded from the wafer housing unit 54.

### (Notch Detecting Step)

A notch detecting step of detecting the position of the notch 9 in the wafer 4 is preferably carried out after the wafer 4 has been unloaded from the wafer housing unit 54.

In the notch detecting step, as illustrated in FIG. 11B, the outer periphery of the wafer 4 supported under suction by the hand 164 is positioned between the light emitting element 174 and the light receiving element 176 of the notch detecting unit 172. Next, the wafer 4 is rotated via the guide pins 170 by the drive source, and the position of the notch 9 in the wafer 4 is detected. This makes it possible to adjust the orientation of the wafer 4 to a desired orientation.

After the notch detecting step is performed, the wafer 4 supported under suction by the hand 164 of the wafer unloading mechanism 64 is conveyed to the frame unit forming table 142 (see FIG. 17). Specifically, the hand 164 of the wafer unloading mechanism 64 is turned upside down to cause the face side 4a of the wafer 4 to face downward. Next, the conveying arm 162 of the wafer unloading mechanism 64 is moved to place the wafer 4 supported under suction by the hand 164 on the wafer supporting portion 156 of the frame unit forming table 142. Subsequently, suction force is generated in the suction holes 160 of the wafer supporting portion 156, and the outer periphery of the face side 4a of the wafer 4 is held under suction. Then, suction-supporting of the wafer 4 by the hand 164 is cancelled, and the hand 164 is separated from the frame unit forming table 142. In this manner, the wafer 4 is delivered from the wafer unloading mechanism 64 to the frame unit forming table 142. The wafer 4 delivered to the frame unit forming table 142 is held under suction by the suction holes 160, and hence, the position of the wafer 4 would not move.

### (Wafer Activation Step)

After the wafer unloading step is performed, a wafer activation step of applying plasma processing or corona treatment to the wafer 4 conveyed to the frame unit forming table 142 is preferably carried out (see FIG. 10).

In the wafer activation step, before the frame sheet 2′ is conveyed to the frame unit forming table 142, the X-, Y-, and Z-axis movable members 224, 228, and 226 of the frame unit unloading means 214 are moved to position the wafer activation unit 232 above the wafer 4 placed on the frame unit forming table 142. Then, the wafer activation unit 232 applies plasma processing or corona treatment to the wafer 4 and activates the wafer 4. This makes it possible to improve the wettability of the surface (reverse side 4b) of the wafer 4 on the side which is to be disposed on the thermocompression bonding sheet 12. The processing to be applied by the wafer activation unit 232 may be atmospheric plasma processing. After plasma processing or corona treatment has been applied to the wafer 4, the frame unit unloading means 214 is separated from the upper side of the frame unit forming table 142. Note that, in the wafer activation step, before plasma processing or corona treatment is applied to the wafer 4, ultraviolet rays may be applied to the surface of the wafer 4 on the side which is to be disposed on the thermocompression bonding sheet 12, to destroy organic matter.

### (Frame Conveying Step)

After the wafer setting step and the frame housing step are performed, in parallel with the wafer unloading step and the notch detecting step, a frame conveying step of unloading the annular frame 2 from the frame housing unit 52 and placing the unloaded annular frame 2 on the frame table 84 is carried out.

Described with reference to FIG. 10, in the frame conveying step, first, the X-axis movable member 88 and the Z-axis movable member 90 of the frame conveying mechanism 56 are moved, and the suction pads 96 of the holding section 92 are brought into contact with the upper surface of the uppermost annular frame 2 housed in the frame housing unit 52. Next, the suction means of the frame conveying mechanism 56 is operated to generate suction force in the suction pads 96, and the uppermost annular frame 2 is held under suction by the suction pads 96. Then, the X-axis movable member 88 and the Z-axis movable member 90 of the frame conveying mechanism 56 are moved to convey the uppermost annular frame 2 held under suction by the suction pads 96 of the holding section 92 from the frame housing unit 52 to the frame table 84. At this time, the frame table 84 is positioned in advance at the delivery position (the position indicated by the solid line in FIG. 10).

### (Activation Step)

After the frame conveying step is performed, an activation step of applying plasma processing or corona treatment to the thermocompression bonding sheet 12 on the side which is to be disposed on the annular frame 2 by the thermocompression bonding sheet disposing unit 58 is carried out.

As illustrated in FIG. 13, in the activation step, first, in a state in which the thermocompression bonding sheet 12 is drawn by the sheet drawing section 104 of the thermocompression bonding sheet disposing unit 58 and the thermocompression bonding sheet 12 from which the peeling paper 112 has been peeled off is stretched with no slack, the thermocompression bonding sheet 12 is positioned above the frame table 84. Next, the activation unit 60 is positioned at the acting position between the thermocompression bonding sheet 12 drawn by the sheet drawing section 104 and the frame table 84. Subsequently, the activation unit 60 applies plasma processing or corona treatment to the thermocompression bonding sheet 12 and activates the thermocompression bonding sheet 12. This can improve the wettability of the thermocompression bonding sheet 12 on the side which is to be disposed on the annular frame 2.

In the activation step, preferably, plasma processing or corona treatment is applied also to the surface of the annular frame 2 (the upper surface of the annular frame 2 placed on the frame table 84) on the side which is to be disposed on the thermocompression bonding sheet 12, to activate the surface of the annular frame 2. This can also improve the wettability of the surface of the annular frame 2 on the side which is to be disposed on the thermocompression bonding sheet 12. Note that the activation step may be performed before the frame conveying step, but performing the activation step after the frame conveying step as in the present embodiment makes it possible to simultaneously apply plasma processing or corona treatment to the thermocompression bonding sheet 12 and the annular frame 2 and activate them. Note that, in the activation step, ultraviolet rays may be applied to the surface to which plasma processing or corona treatment is to be applied, to destroy organic matter, before plasma processing or corona treatment is applied.

### (Thermocompression Bonding Sheet Disposing Step)

After the activation step is performed, a thermocompression bonding sheet disposing step of disposing the thermocompression bonding sheet 12 on the annular frame 2 placed on the frame table 84 is carried out.

In the thermocompression bonding sheet disposing step, first, the temperature of the outer peripheral surface of the heating roller 126 is adjusted to a temperature at which the thermocompression bonding sheet 12 exhibits adhesion by softening or melting. Next, as illustrated in FIG. 14, the frame table 84 is positioned at a thermocompression bonding start position, and the heating roller 126 of the thermocompression bonding sheet disposing unit 58 is lowered to the lower side pressing position to thermocompression-bond the thermocompression bonding sheet 12 to one end of the annular frame 2 with tension being applied to the thermocompression bonding sheet 12. At this time, the thermocompression bonding sheet 12 forms an elevation angle α from the heating roller 126 toward the guide roller 124 that is on the lower side of the sheet winding section 102.

Thereafter, while pressing the thermocompression bonding sheet 12 against the annular frame 2, the heating roller 126 is moved in the Y-axis direction toward the other end of the annular frame 2. As a result, the thermocompression bonding sheet 12 is heated to exhibit adhesion, and can thus be thermocompression-bonded to the annular frame 2.

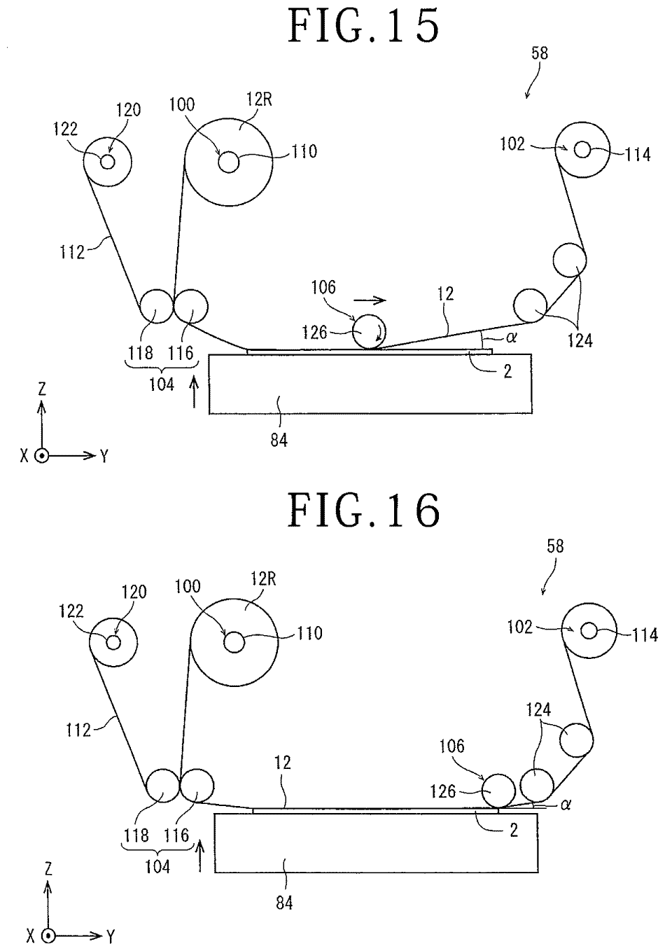

When the heating roller 126 is moved, the frame table 84 is lifted in synchronization with the movement of the heating roller 126, to keep the tension applied to the thermocompression bonding sheet 12 constant. Specifically, as illustrated in FIGS. 15 and 16, the frame table 84 is gradually lifted in synchronization with the movement of the heating roller 126 to keep the elevation angle α constant. As a result, the thermocompression bonding sheet 12 can be thermocompression-bonded to the annular frame 2 in a state in which substantially uniform tension is applied to the thermocompression bonding sheet 12. Note that, in the thermocompression bonding sheet disposing step, instead of the temperature of the heating roller 126 being adjusted, the temperature of the upper surface of frame table 84 may be adjusted to a temperature at which the thermocompression bonding sheet 12 exhibits adhesion by softening or melting.

Described with reference to FIG. 12, after the thermocompression bonding sheet 12 is thermocompression-bonded to the annular frame 2, the Z-axis movable member 130 of the cutting section 108 is lowered, so that the cutter 138 is pressed against the thermocompression bonding sheet 12 on the annular frame 2 and the pressing roller 140 presses the annular frame 2 over the thermocompression bonding sheet 12. Next, the arm piece 134 is rotated by the motor 132, and the cutter 138 and the pressing roller 140 are moved in such a manner as to draw a circle along the annular frame 2. This allows the thermocompression bonding sheet 12 sticking out from the outer periphery of the annular frame 2 to be cut along the annular frame 2. Moreover, since the pressing roller 140 presses the annular frame 2 over the thermocompression bonding sheet 12, the annular frame 2 or the thermocompression bonding sheet 12 are prevented from being misaligned while the thermocompression bonding sheet 12 is being cut. After the thermocompression bonding sheet 12 is cut, the frame table 84 is lowered, and the used thermocompression bonding sheet 12 in which a circular opening portion 12a corresponding to a portion that has been thermocompression-bonded to the annular frame 2 is formed is wound up by the winding section 102.

### (Frame Sheet Conveying Step)

After the thermocompression bonding sheet disposing step is performed, a frame sheet conveying step of conveying the frame sheet 2′ (the annular frame 2 on which the thermocompression bonding sheet 12 is disposed) to the frame unit forming table 142 is carried out (see FIG. 10).

In the frame sheet conveying step, first, the frame table 84 is lowered to the delivery position (the position illustrated by the solid line in FIG. 10). Next, the Y-axis movable member 146 and the Z-axis movable member 148 of the frame sheet conveying mechanism 62 are moved, and the suction pads 154 of the holding section 150 of the frame sheet conveying mechanism 62 are brought into contact with the upper surface of the frame sheet 2′ supported on the frame table 84. Subsequently, the suction means of the frame sheet conveying mechanism 62 is operated to generate suction force in the suction pads 154, and the upper surface of the frame sheet 2′ is held under suction by the suction pads 154. Thereafter, the Y-axis movable member 146 and the Z-axis movable member 148 of the frame sheet conveying mechanism 62 are moved, and the frame sheet 2′ held under suction by the suction pads 154 is unloaded from the frame table 84.

Next, the frame sheet 2′ held under suction by the suction pads 154 of the frame sheet conveying mechanism 62 is conveyed to the frame unit forming table 142, and as illustrated in FIG. 17, the frame sheet 2′ is brought into contact with the frame supporting portion 158 of the frame unit forming table 142 with the opening portion 2a of the annular frame 2 being positioned on the reverse side 4b of the wafer 4 supported by the frame unit forming table 142. Subsequently, the suction force of the suction pads 154 of the frame sheet conveying mechanism 62 is cancelled, and the frame sheet 2′ is placed on the frame supporting portion 158. Then, the Y-axis movable member 146 and the Z-axis movable member 148 of the frame sheet conveying mechanism 62 are moved, and the holding section 150 is separated from the upper side of the frame unit forming table 142.

### (Frame Unit Forming Step)

After the frame sheet conveying step is performed, a frame unit forming step of forming the frame unit 16 by integrating the wafer 4 with the frame sheet 2′ conveyed to the frame unit forming table 142 is carried out.

In the frame unit forming step, first, the upper chamber 178 is lowered by the lifting and lowering mechanism 182 of the frame unit forming mechanism 66, and the lower end of the sidewall 190 of the upper chamber 178 is brought into contact with the upper end of the sidewall 204 of the lower chamber 180. As a result, the upper chamber 178 and the lower chamber 180 are set to the closed state, and the heating roller 192 is brought into contact with the frame sheet 2′.

Thereafter, the vacuum section 184 is operated in a state in which the atmospheric opening section 186 of the frame unit forming mechanism 66 is closed, and the inside of the upper chamber 178 and the lower chamber 180 is vacuumed. Then, after the temperature of the heating roller 192 is adjusted to a temperature at which the thermocompression bonding sheet 12 exhibits adhesion by softening or melting, the heating roller 192 is rolled in the Y-axis direction. As a result, the thermocompression bonding sheet 12 is heated to exhibit adhesion, and can thus be thermocompression-bonded to the reverse side 4b of the wafer 4. Consequently, the frame unit 16 is formed. Thereafter, the atmospheric opening section 186 is opened, and the thermocompression bonding sheet 12 is brought into tight contact with the wafer 4 by atmospheric pressure. Subsequently, the upper chamber 178 is lifted by the lifting and lowering mechanism 182. Note that, in the frame unit forming step, instead of the temperature of the heating roller 192 being adjusted, the temperature of the upper surface of the wafer supporting portion 156 may be adjusted to a temperature at which the thermocompression bonding sheet 12 exhibits adhesion by softening or melting.

### (Cassette Housing Step)

After the frame unit forming step is performed, a cassette housing step of housing the frame unit 16 in the cassette 212 is carried out.

Described with reference to FIG. 10, in the cassette housing step, first, the frame unit 16 is unloaded from the frame unit forming table 142 by the frame unit unloading means 214. Specifically, the X-, Y-, and Z-axis movable members 224, 228, and 226 are moved, and the suction pads 236 are brought into contact with the annular frame 2. Next, suction force is generated in the suction pads 236, and the annular frame 2 is held under suction by the suction pads 236. Subsequently, suction-holding of the wafer 4 by the frame unit forming table 142 is cancelled. Then, the X-, Y-, and Z-axis movable members 224, 228, and 226 are moved, and the frame unit 16 is unloaded from the frame unit forming table 142.

After being unloaded from the frame unit forming table 142, the frame unit 16 is delivered from the frame unit unloading means 214 to the inverting mechanism 216 (see FIG. 9). At this time, the board 246 of the inverting mechanism 216 is positioned below the frame unit 16 held by the frame unit unloading means 214. Then, the arm 242 is raised in a state in which the suction pads 250 of the board 246 are facing upward, so that the suction pads 250 are brought into contact with the lower surface side of the annular frame 2 of the frame unit 16 that is in a state of being held by the frame unit unloading means 214 and that has the face side 4a of the wafer 4 facing downward. Next, suction force is generated in the suction pads 250, and the annular frame 2 of the frame unit 16 is held under suction by the suction pads 250. Then, suction-holding of the frame unit 16 by the frame unit unloading means 214 is cancelled. In this manner, the frame unit 16 is delivered from the frame unit unloading means 214 to the inverting mechanism 216.

After being delivered from the frame unit unloading means 214 to the inverting mechanism 216, the frame unit 16 is then delivered from the inverting mechanism 216 to the frame unit supporting section 218 (see FIGS. 18 and 19). At this time, first, the board 246 of the inverting mechanism 216 is turned upside down, to turn upside down the frame unit 16 held under suction by the suction pads 250. As a result, the frame unit 16 is positioned below the board 246, and the face side 4a of the wafer 4 faces upward. Next, the Y-axis movable member 240 and the arm 242 of the inverting mechanism 216 are moved, and the frame unit 16 is brought into contact with the upper surface of the pair of support plates 252 of the frame unit supporting section 218. Then, suction-holding of the frame unit 16 by the suction pads 250 is cancelled. In this manner, the frame unit 16 is delivered from the inverting mechanism 216 to the frame unit supporting section 218.

After the frame unit 16 is delivered from the inverting mechanism 216 to the frame unit supporting section 218, as illustrated in FIG. 20, the Y-axis movable member 256 of the pushing-in section 220 is moved in the Y-axis direction, so that the frame unit 16 supported by the frame unit supporting section 218 is caused to enter the cassette 212 placed on the cassette table 210 and to be housed therein by the pressing piece 262.

As described above, according to the present embodiment, the frame unit 16 is formed by the thermocompression bonding sheet 12 including no glue layer, so that the problem of glue scattering together with cutting water and sticking to the face sides of the devices 8 to lower the quality of the device chips 8 at the time when the wafer 4 is cut by the cutting blade 24 can be resolved. Moreover, even when the dicing grooves (laser processing grooves 32) or the modified layers 34 as initiating points for dicing are formed with application of the laser beam LB to the projected dicing lines 6 in the wafer 4, the thermocompression bonding sheet 12 includes no glue layer, so that the problem of glue sticking to the devices 8 to lower the quality of the device chips 8 and to eventually become the source of contamination in the subsequent pickup step can be resolved.

Further, according to the present embodiment, since plasma processing or corona treatment is applied to the surface of the thermocompression bonding sheet 12 on the side on which the wafer 4 and the annular frame 2 are to be disposed and the surface of the thermocompression bonding sheet 12 is activated, the adhesiveness of the thermocompression bonding sheet 12 with respect to the wafer 4 and the annular frame 2 can be enhanced, and no water in which processing swarf generated at the time of dicing by the cutting blade is mixed would enter any portion between the thermocompression bonding sheet 12 and the wafer 4. This would also prevent lowered quality of the device chips 8.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A frame unit forming method of forming a frame unit by integrating a wafer with an annular frame that has, at its center, an opening portion for housing the wafer, the frame unit forming method comprising:
disposing the wafer on the opening portion of the annular frame;
forming the frame unit by disposing a thermocompression bonding sheet on the wafer and an outer periphery of the annular frame and integrating the wafer with the annular frame by the thermocompression bonding sheet; and
activating, before the forming the frame unit, a surface of the thermocompression bonding sheet on a side which is to be disposed on the wafer and the annular frame, by applying plasma processing or corona treatment to the surface of the thermocompression bonding sheet.

2. The frame unit forming method according to claim 1, wherein, in the activating, plasma processing or corona treatment is applied to a surface of the wafer and a surface of the annular frame on a side which is to be disposed on the thermocompression bonding sheet, to activate the surfaces of the wafer and the annular frame.

3. The frame unit forming method according to claim 1, wherein, in the activating, atmospheric plasma processing is applied.

4. A frame unit forming apparatus for forming a frame unit with use of a thermocompression bonding sheet by housing a wafer in an opening portion of an annular frame that is provided at a center thereof for housing the wafer, the frame unit forming apparatus comprising:
a frame housing unit that houses a plurality of the annular frames;
a wafer housing unit that houses a plurality of wafers;
a frame conveying mechanism that unloads the annular frame from the frame housing unit and places the unloaded annular frame on a frame table;
a thermocompression bonding sheet disposing unit that disposes the thermocompression bonding sheet on the annular frame placed on the frame table;
a frame sheet conveying mechanism that conveys the annular frame on which the thermocompression bonding sheet is disposed to a frame unit forming table;
a wafer unloading mechanism that unloads the wafer from the wafer housing unit and conveys the unloaded wafer to the frame unit forming table;
a frame unit forming mechanism that forms the frame unit by integrating the wafer with the annular frame on which the thermocompression bonding sheet is disposed and which has been conveyed to the frame unit forming table;
a cassette housing unit that houses the frame unit in a cassette; and
an activation unit that applies plasma processing or corona treatment to the thermocompression bonding sheet on a side which is to be disposed on the annular frame by the thermocompression bonding sheet disposing unit.

5. The frame unit forming apparatus according to claim 4, further comprising:
a wafer activation unit that applies plasma processing or corona treatment to the wafer that has been conveyed to the frame unit forming table.

6. A method of forming device chips comprising:
disposing a wafer on an opening portion of an annular frame;
forming a frame unit by disposing a thermocompression bonding sheet on the wafer and an outer periphery of the annular frame and integrating the wafer with the annular frame by the thermocompression bonding sheet;
dividing, after the forming the frame unit, the wafer into individual device chips; and
activating, before the forming the frame unit, a surface of the thermocompression bonding sheet on a side which is to be disposed on the wafer and the annular frame, by applying plasma processing or corona treatment to the surface of the thermocompression bonding sheet.
